(19) United States
(12) Patent Application Publication
(10) Pub. No.: US 2024/0234256 A1
(43) Pub. Date: Jul. 11, 2024

(54) PACKAGE WITH VACUUM SUCTION ENHANCING INDENTATION ON BACK SIDE OF CARRIER

(71) Applicant: Infineon Technologies AG, Neubiberg (DE)

(72) Inventors: Nor Samsiah MARZUKI, Melaka (MY); Arivindran NAVARETNASINGGAM, Seremban (MY); Narayanan CHELLIAH, Melaka (MY); Ke Yan TEAN, Melaka (MY); Rolando Pontillas ENVERGA, Barangay Batingan (PH)

(73) Assignee: Infineon Technologies AG, Neubiberg (DE)

(21) Appl. No.: 18/518,837

(22) Filed: Nov. 24, 2023

(30) Foreign Application Priority Data
Jan. 9, 2023 (DE) 10 2023 100 284.8

(51) Int. Cl. H01L 23/495; H01L 21/56; H01L 23/31

(52) U.S. Cl. CPC H01L 23/49503; H01L 21/565; H01L 23/3121; H01L 24/48; H01L 2224/48091; H01L 2224/48245

(57) ABSTRACT

A package is disclosed. In one example, the package comprises a carrier having a front side and a back side, an electronic component mounted on the front side of the carrier, and an encapsulant at least partially encapsulating the electronic component and partially encapsulating the carrier so that the back side is at least partially exposed with respect to the encapsulant. The back side of the carrier has at least one vacuum suction enhancing indentation for enhancing vacuum suction of the carrier during encapsulation.

### CROSS-REFERENCE TO RELATED APPLICATION

This Utility Patent application claims priority to German Patent Application No. 10 2023 100 284.8 filed Jan. 9, 2023, which is incorporated herein by reference.

### BACKGROUND

### Technical Field

Various embodiments relate generally to a package, and a method of manufacturing a package.

### Description of the Related Art

A conventional package may comprise an electronic component mounted on a chip carrier such as a leadframe, may be electrically connected by a bond wire extending from the chip to the chip carrier or to a lead, and may be molded using a mold compound as an encapsulant.

### SUMMARY

There may be a need for a package with high reliability and reasonable manufacturing effort.

According to an exemplary embodiment, a package is provided which comprises a carrier having a front side and a back side, an electronic component mounted on the front side of the carrier, and an encapsulant at least partially encapsulating the electronic component and partially encapsulating the carrier so that the back side is at least partially exposed with respect to the encapsulant, and wherein the back side of the carrier has at least one vacuum suction enhancing indentation for enhancing vacuum suction of the carrier during encapsulation.

According to another exemplary embodiment, a method of manufacturing a package is provided, the method comprising providing a carrier having a front side and a back side, mounting an electronic component on the front side of the carrier, at least partially encapsulating the electronic component and partially encapsulating the carrier by an encapsulant so that the back side is at least partially exposed with respect to the encapsulant, and applying a vacuum suction force to the back side of the carrier during the encapsulating, wherein the back side of the carrier has at least one vacuum suction enhancing indentation for enhancing the vacuum suction of the carrier.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of a package according to an exemplary embodiment arranged in an encapsulation tool.

FIG. 2 illustrates a flowchart of a method of manufacturing a package according to an exemplary embodiment.

FIG. 3 to FIG. 5 illustrate different views of arrangements during manufacturing a package according to an exemplary embodiment.

FIG. 6 illustrates a plan view of a package according to an exemplary embodiment.

FIG. 7 illustrates a plan view of a package according to an exemplary embodiment.

FIG. 8 illustrates a plan view of a package according to an exemplary embodiment.

FIG. 9 illustrates a plan view of a package according to an exemplary embodiment.

FIG. 10 illustrates a plan view and a cross-sectional view of a package according to an exemplary embodiment.

### DETAILED DESCRIPTION

There may be a need for a package with high reliability and reasonable manufacturing effort.

According to an exemplary embodiment, a package is provided which comprises a carrier having a front side and a back side, an electronic component mounted on the front side of the carrier, and an encapsulant at least partially encapsulating the electronic component and partially encapsulating the carrier so that the back side is at least partially exposed with respect to the encapsulant, and wherein the back side of the carrier has at least one vacuum suction enhancing indentation for enhancing vacuum suction of the carrier during encapsulation.

According to another exemplary embodiment, a method of manufacturing a package is provided, the method comprising providing a carrier having a front side and a back side, mounting an electronic component on the front side of the carrier, at least partially encapsulating the electronic component and partially encapsulating the carrier by an encapsulant so that the back side is at least partially exposed with respect to the encapsulant, and applying a vacuum suction force to the back side of the carrier during the encapsulating, wherein the back side of the carrier has at least one vacuum suction enhancing indentation for enhancing the vacuum suction of the carrier.

According to an exemplary embodiment, a package is provided which has a carrier (for instance a leadframe structure) with one or more electronic components mounted on a front side thereof. An encapsulant (such as a mold compound) may encapsulate the electronic component and part of the carrier so that at least a portion of a back side thereof is exposed beyond the encapsulant. Advantageously, said carrier back side is provided with one or more vacuum suction enhancing indentations (or recesses) which may be configured for enhancing or improving a vacuum suction performance according to which the carrier is held at an encapsulation tool during an encapsulation process. Descriptively speaking, a vacuum suction enhancing indentation may promote planarity of the carrier and/or may ensure a safe rest of the back side of the carrier on a bottom-sided encapsulation tool. Also the risk of flashes or contamination of the carrier back side with encapsulant residues may be mitigated by the one or more vacuum suction enhancing indentations. At said bottom side, one or more vacuum suction openings may keep the carrier firmly attached to the bottom side by an encapsulation-supporting vacuum suction force. Such a planar and firm contact of the bottom side of the carrier on the bottom-sided encapsulation tool may be enhanced by the at least one vacuum suction enhancing indentation which may lead to a reliable encapsulation process. Furthermore, the at least one vacuum suction enhancing indentation may also inhibit encapsulant material from flowing unintentionally onto a central bottom-sided region of the carrier. This may ensure that at least a portion of the back side of the carrier remains reliably free of any encapsulant material. Since encapsulant material (such as a mold compound) may have a significantly lower thermal conductivity than carrier material (such as a metal), maintaining at least a portion of the back side of the carrier free from encapsulant material may efficiently promote removal of heat, generated by the electronic component during operation, out of the package. Thus, a package according to an exemplary embodiment may be manufactured with high thermal reliability. At the same time, fixing a carrier with surface mounted electronic component at a bottom-sided encapsulation tool by vacuum suction during encapsulation supported by at least one vacuum suction enhancing indentation may lead to a reasonable manufacturing effort of the package, since auxiliary tools such as tie bars and pins may be dispensable. When omitting a pin—which may be dispensable due to the vacuum supported encapsulation of an exemplary embodiment—a full front side area of the carrier may become available for assembling an electronic component, so that the package may be made more compact or may be equipped with larger electronic component(s). The absence of tie bars at a package surface may improve electric reliability.

### DESCRIPTION OF FURTHER EXEMPLARY EMBODIMENTS

In the following, further exemplary embodiments of the package and the method will be explained.

In the context of the present application, the term “package” may particularly denote an electronic device which may comprise one or more electronic components mounted on a (in particular electrically conductive) carrier. Said constituents of the package may be encapsulated at least partially by an encapsulant. Optionally, one or more electrically conductive interconnect bodies (such as metallic pillars, bumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate. Also at least part of the carrier may be encapsulated by the encapsulant, together with the electronic component.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

In the context of the present application, the term “encapsulant” may particularly denote a substantially electrically insulating material surrounding at least part of an electronic component and part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In the context of the present application, the term “vacuum suction enhancing indentation” may in particular denote any recess in a (apart from this preferably planar) back-sided main surface of a carrier which promotes a vacuum suction force exerted to the back side of the carrier. In particular, a vacuum suction enhancing indentation may ensure that the carrier is firmly fixed on a bottom-sided encapsulation tool during encapsulation. For example, the at least one vacuum suction enhancing indentation may comprise a groove, in particular a circumferentially closed groove, and/or a blind hole or cavity, provided that such an indentation may enhance vacuum suction of the carrier during encapsulation. In particular, a vacuum suction enhancing indentation may be any surface profile extending into a planar surface of the back side of the carrier which is configured for enhancing a contact between back side of the carrier and bottom-sided encapsulation tool during encapsulation.

In the context of the present application, the term “vacuum suction force” may in particular denote any force being created at least partially by a vacuum or negative pressure and being exerted to a back side of a carrier when placed on a bottom-sided encapsulation tool. Such a vacuum suction force may promote a firm, preferably two-dimensional, direct physical contact between at least part of the back side of the carrier and the bottom-sided encapsulation tool by a vacuum or negative pressure pulling the carrier onto or towards the bottom-sided encapsulation tool. In particular, a vacuum suction force may be generated by one or more openings in the bottom-sided encapsulation tool providing a negative pressure on vacuum. Such a vacuum opening may be connected with a vacuum tube, vacuum nozzle, etc. A vacuum opening may be connected with a vacuum source, such as a vacuum pump or an evacuated space providing the vacuum.

In an embodiment, the at least one vacuum suction enhancing indentation is configured for enhancing flatness of the carrier during vacuum suction. In particular, flatness of the back side of the carrier may be improved when a vacuum opening of the bottom-sided encapsulation tool impacts a continuous two-dimensional indentation on the back side of the carrier. Bending or warpage of the carrier may be reliably prevented when a flatness promoting vacuum suction enhancing indentation is foreseen.

In an embodiment, the at least one vacuum suction enhancing indentation is configured for inhibiting a flow of encapsulant during encapsulation to the at least partially exposed back side. In such a preferred embodiment, it may be reliably prevented by the at least one vacuum suction enhancing indentation that still flowable encapsulant material (i.e. encapsulant material which is not yet cured or hardened) unintentionally flows along the back side of the carrier. Thus, a vacuum suction enhancing indentation may function as an additional barrier or obstacle for an unintentional flow of encapsulant material onto the back side of the carrier. Furthermore, such a vacuum suction enhancing indentation may also accommodate excessive encapsulant material, thereby preventing mode flash.

In an embodiment, the at least one vacuum suction enhancing indentation comprises a groove. Preferably but not necessarily, the groove may be a circumferentially closed groove. In particular, the aforementioned mitigation of mold flow onto a central portion of the back side of the carrier may be achieved for example by a vacuum suction enhancing indentation embodied as a closed loop groove. Descriptively speaking, such an annular groove may extend circumferentially the length of a flow path of flowable encapsulant material from a lateral position of the carrier towards a center of its back side, since the flowable encapsulant must also pass the additional flow path portion added by the groove. Furthermore, such a groove may render the mentioned flow path more complex, since encapsulant material has to flow around additional corners to proceed into an unwanted region. Consequently, a groove and more preferably a closed loop groove may also efficiently inhibit an unintentional flow of encapsulant material onto a central portion of the back side of the carrier. Furthermore, excessive encapsulant material may also be captured by the groove and may be accommodated therein.

In an embodiment, the groove is rectangular, circular or oval. Any other groove shape is possible as well. While a circumferentially closed groove is preferred, also one or more open groove sections may have a positive impact on package reliability. Beyond this, a plurality of grooves, for instance concentric grooves, may be possible as well for further suppressing encapsulant flow into undesired regions of the back side of the carrier. To put it shortly, one or a plurality of open and/or closed-loop grooves may be a possible embodiment of at least part of the at least one vacuum suction enhancing indentation.

In an embodiment, the groove has a width in a range from 50 μm to 200 μm, in particular from 70 μm to 150 μm. These dimensions may maintain the mechanical integrity of the carrier while at the same time sufficiently inhibiting undesired mold flow along the back side. In this context, the width of the groove may be the shorter of the two dimensions of the groove in the plane of the back side of the carrier. In the other dimension—i.e. in the length dimension—of the plane of the back side of the carrier, the groove may have a significantly longer extension, for example at least 10 mm.

In an embodiment, the at least one vacuum suction enhancing indentation comprises at least one interior indentation in an interior of an exterior circumferentially closed groove. In such a preferred embodiment, the exterior groove suppressing undesired flow of flowable encapsulant material may be combined with an interior indentation, for instance embodied as cavity or further groove. Such an interior indentation may ensure good planarity of the carrier on and in the encapsulation tool. Descriptively speaking, one or more vacuum openings in a bottom-sided encapsulation tool may be brought in gas communication with an interior indentation on the back side of the carrier to thereby enhance planarity.

In an embodiment, the at least one vacuum suction enhancing indentation comprises a continuous two-dimensional cavity. For example, such a vacuum suction enhancing indentation may be a two-dimensional blind hole in the back side of the carrier having length and width within the back side plane each being much larger than, in particular being at least five times or at least ten times of, a depth of such a cavity.

In an embodiment, the continuous two-dimensional cavity is rectangular, circular or oval. For instance, such an interior indentation may have a polygonal (for example rectangular) or round (for example circular) shape. For example, a two dimensionally indented area may have an area value in the back side of the carrier of at least 25 mm², in particular of at least 100 mm². A depth of the two-dimensional indented area may be smaller than length and width. Hence, the two-dimensional indented area may be a shallow cavity. It is also possible that a plurality of two-dimensional indented areas are formed in the back side of the carrier. Also at least one groove in addition to at least one two-dimensional indented area is possible, since this may allow to achieve both a good planarity and a reliable protection of a central exposed portion of the back side of the carrier against contamination with encapsulant material.

In an embodiment, the encapsulant and the carrier together delimit the entire exterior surface of the package. In other words, the entire outline of the package may be defined by carrier and encapsulant. The encapsulant may be a mold compound. The carrier may comprise a die pad and leads, which may both be formed as part of a leadframe structure. In the described embodiment, no further constituent of the package may form part of its exterior surface.

In the described embodiment, no tie bar may extend to the exterior surface of the package. Thus, an outline of the package may be free of a tie bar. Tie bars may be used for interconnecting constituents of different packages during manufacture. In many cases, tie bars are made of metal, and may for example form part of a leadframe. During separating individual packages manufactured in a batch procedure, said tie bars may be separated as well. However, cutting through metallic tie bar material may be cumbersome and may decelerate the separation process. Due to the manufacturing architecture of an exemplary embodiment, cutting through tie bars may be dispensable, since tie bars may be omitted in particular in regions in which packages are singularized.

In an embodiment, the package is configured as tie bar-less package. In such an embodiment, the entire package may be entirely free of any tie bar. This may simplify the manufacturing process and may improve the electric reliability of the package, since no metallic tie bar material will then form part of the exterior surface of the package.

In an embodiment, clamp pins and tie bars may be dispensable due to the vacuum-supported manufacturing process, which is promoted on package level by the at least one vacuum suction enhancing indentation on the back side of the carrier.

In an embodiment, the carrier is a leadframe structure. Preferably, such a leadframe-type carrier comprises a die paddle or die pad, on which the electronic component is mounted and which has the at least one vacuum suction enhancing indentation. Furthermore, such a leadframe-type carrier may comprise at least one lead, preferably a plurality of leads. A leadframe structure may be a metal structure of the package that carries signals from the electronic component to the outside, and/or in opposite direction.

In an embodiment, a depth of the at least one vacuum suction enhancing indentation is in a range from 5 μm to 100 μm, in particular in a range from 10 μm to 30 μm. A plate-shaped carrier with a back side having at least one vacuum suction enhancing indentation with the mentioned depth may on the one hand contribute significantly to a carrier's planarity and reliable exposure beyond encapsulant. On the other hand, at least one vacuum suction enhancing indentation of the mentioned depth may also ensure mechanical integrity and structural stability of the carrier. In particular, the mentioned depth values are sufficiently small to ensure that the front side of the carrier, on which at least one electronic component is mounted, may remain planar and unaffected from the vacuum suction enhancing feature(s) on the back side, for instance formed by coining.

In an embodiment, a thickness of the carrier is in a range from 200 μm to 1200 μm, in particular in a range from 500 μm to 900 μm. In particular with such relatively thin metallic carriers, planarity may be an issue what concerns chip assembly and encapsulation. At the same time, opportunities of improving planarity and protecting the back side against unintentional coverage with encapsulant material are limited due to the package design. Thus, formation of a surface profile on the back side of such a carrier is a surprisingly simple measure which efficiently improves the back side attributes of the carrier while being compatible with the mentioned thickness ranges. However, the thickness of the carrier may be significantly larger than the thickness of the at least one vacuum suction enhancing indentation to ensure that the front side of the carrier may remain planar for promoting accurate chip assembly.

In an embodiment, the front side of the carrier is flat. Hence, regardless of the one or more vacuum suction enhancing indentations in the back side, the front side of the carrier may be planar. This may be advantageous, since this may promote the accuracy of the die attach on the front side of the carrier.

In an embodiment, the method comprises forming the at least one vacuum suction enhancing indentation by at least one of the group consisting of coining, mechanical abrasion, and etching. For instance, the surface profile in the back-side of the carrier constituting the at least one vacuum suction enhancing indentation may be formed by coining or stamping, etching and/or mechanical abrasion such as milling. For example, it may be easily possible to coin or stamp a flat back side of the carrier, for instance using a master mold, to thereby form the surface profile in accordance with a target shape and arrangement of the at least one vacuum suction enhancing indentation. Alternatively, a lithography and etching process may be executed for selectively back etching defined surface portions of the back side of the carrier for forming a corresponding surface profile. In yet another embodiment, the surface profile may be milled. Another possibility for forming the surface pattern is rolling. For example, dual (or multiple) gauge rolling may be executed in this context, which is in particular appropriate for small dimensions.

In an embodiment, the method comprises placing the back side of the carrier on a bottom of an encapsulation tool and pulling the carrier towards the bottom by applying the vacuum suction force through the bottom of the encapsulation tool during encapsulating. When applying a vacuum to at least one opening in the bottom of the encapsulation tool on which the back side of the carrier rests, the back side of the carrier may be sucked onto the bottom of the encapsulation tool with direct physical contact. This promotes planarity of a plate-shaped area and prevents flowable encapsulant from unintentionally coating a significant surface area of the carrier's back side.

In an embodiment, the method comprises placing at least one vacuum suction opening of an encapsulation tool onto a portion of the back side of the carrier during encapsulating, which portion has the at least one vacuum suction enhancing indentation. When aligning a respective vacuum suction opening of the bottom of the encapsulation tool with an assigned vacuum suction enhancing indentation on the back side of the carrier, it may be ensured that the vacuum suction force provided by said vacuum suction opening will directly act via said vacuum suction enhancing indentation onto a back side surface of the carrier for efficiently pulling the carrier downward onto the bottom of the encapsulation tool.

In an embodiment, the package is configured as power package. A power package may be a package comprising at least one power chip as encapsulated electronic component. Thus, the package may be configured as power module, for instance molded power module such as a semiconductor power package. For instance, an exemplary embodiment of the package may be an intelligent power module (IPM). Another exemplary embodiment of the package is a dual inline package (DIP).

Correspondingly, the electronic component may be configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc. Advantages of exemplary embodiments concerning isolation and thermal dissipation are particularly pronounced for power dies.

In an embodiment, the package comprises a heat sink mounted on an exposed surface of the back side of the carrier. Such a heat sink may be a heat dissipation body, which may be made of a highly thermally conductive material such as copper or aluminum which may be attached directly, or via a thermal interface material (TIM), to the back side of the carrier. For instance, such a heat sink may have a base body being directly connected to said exposed back side of the carrier and may have a plurality of cooling fins extending from the base body and in parallel to each another so as to remove the heat towards the environment.

It is also possible that the exposed carrier itself functions as heat sink for cooling purposes.

In an embodiment, the package comprises at least one electrically conductive coupling element electrically coupling the electronic component with the carrier (in particular with the die pad and/or with at least one lead). Such an electrically conductive coupling element may be a clip, a bond wire or a bond ribbon. A clip may be a curved electrically conductive body accomplishing an electric connection with a high connection area to an upper main surface of a respective electronic component. Additionally or alternatively to such a clip, it is also possible to implement one or more other electrically conductive interconnect bodies in the package, for instance a bond wire and/or a bond ribbon connecting the electronic component with the die pad and/or a lead or connecting different pads of an electronic component.

For example, the package may be configured as a Quadrupole DPAK (QDPAK) package. However, a package according to other exemplary embodiments may also be configured as one of the group consisting of a leadframe connected power module, a Control integrated power system (CIPOS) package, a Transistor Outline (TO) package, a Quad Flat No Leads Package (QFN) package, a Small Outline (SO) package, a Small Outline Transistor (SOT) package, and a Thin Small Outline Package (TSOP) package. For example, the package may be implemented in a “CIPOS™ Mini” configuration or a “TO-247” configuration of the applicant Infineon Technologies AG. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts and appears externally as a conventional package, which is highly user convenient.

As substrate or wafer forming the basis of the electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Conventionally, a package with an encapsulated semiconductor chip may comprise one or more tie bars. However, such tie bars may have an undesired impact on the creepage behavior of the package. Conventional package may also require a retractable pin supporting an encapsulation process. However, such a retractable pin may limit the die size in the package.

According to an exemplary embodiment, a package comprises a carrier (such as a leadframe structure) having a front side and a back side. One or more electronic components (for instance a power semiconductor chip) may be mounted on the front side. An encapsulant (such as a mold compound) may encapsulate electronic component and part of the carrier while leaving at least part of its back side exposed. Advantageously, the back side of the carrier has one or a plurality of vacuum suction enhancing indentations. The latter may enhance vacuum suction of the carrier during encapsulation. A vacuum suction enhancing indentation may be manufactured in a simple way as a specific back side surface profile of the carrier and may render tie bars and pins, supporting a conventional encapsulation process, unnecessary. This may simplify the manufacturing process and may improve the electric reliability of the package. By ensuring planarity and/or inhibiting mold flow onto the back side of the carrier, the vacuum suction enhancing indentation may improve the thermal reliability of the package, since a thermal barrier of poorly thermally conductive encapsulant on the back side of the carrier may be reliably prevented.

To put it shortly, an exemplary embodiment may provide a fully insulated package being manufacturable in a clamp-free way. Moreover, such a package may be provided with a tie bar-less configuration. Such a package may be manufactured by a selective vacuum process compliant with high voltage requirements.

Thus, a selective vacuum mold package may be provided so as to be compatible with high voltage applications. When omitting pins during encapsulation, the package may be equipped with electronic components (such as semiconductor dies) of larger die size, since the front side of the carrier is not influenced or limited by such these pins. These advantages may be achieved or at least supported by a simple special feature at the exposed heat sink-side of the carrier. Said feature, i.e. at least one vacuum suction enhancing indentation, may efficiently enhance vacuum suction of a die pad-type carrier portion during an encapsulation (in particular a mold) process.

More specifically, a bottom mold cavity may be designed with a selective vacuum source to hold the heat sink-type carrier downwardly during encapsulation. Said heat sink-type carrier may be provided with at least one vacuum suction enhancing indentation, which may be embodied for example as a recess in the bottom side of the carrier. Such an indentation may for example have a depth of 30 μm and a width of 100 μm.

For example, the package may be embodied as a high voltage QDPAK with a tie bar-less leadframe and without clamps using vacuum mold.

A package of an exemplary embodiment may use a selective vacuum mold process as a clamping method. A mold bottom may be equipped with a cavity design to hold a heat sink-carrier with selective vacuum during encapsulation. For example, a corresponding heat sink groove design may be done with certain depth and width to enhance the vacuum suction towards a die pad of the carrier. This may lead to a fully insulated package enabling sufficient space on the front side of the carrier for a larger die size on the die pad. Advantageously, such a package may be manufactured without the use of a retractable pin, but in contrast to this with a selective vacuum mold process as an alternative to pin clamping. This may allow to manufacture a tie bar-less package with reasonable effort.

To put it shortly, an exemplary embodiment provides a package with at least one vacuum suction enhancing indentation (such as a group) on a bottom of a leadframe-type carrier to promote vacuum suction of the carrier onto a bottom of an encapsulation tool. Advantageously, such a groove may be of a closed loop type for providing a reliable protection during vacuum suction. Descriptively speaking, such a closed loop groove may function as a protection structure on a bottom side of a carrier for delimiting a vacuum suction region. It is also possible that a vacuum suction enhancing indentation is provided which functions for providing interaction with one or more vacuum suction nozzles. Such a vacuum suction enhancing indentation may promote a flat bottom surface of the carrier during vacuum suction. Such a design may be of particular advantage for a tie bar-less package without encapsulation-supporting pin. A corresponding package may be particularly appropriate for high-voltage applications and for applications using a large size die. To put it shortly, the at least one vacuum suction enhancing indentation may be configured for pulling downwardly a heat sink-type carrier having at least one bottom recess. In contrast to the profiled back side of the carrier, its component-carrying front side may be flat and planar.

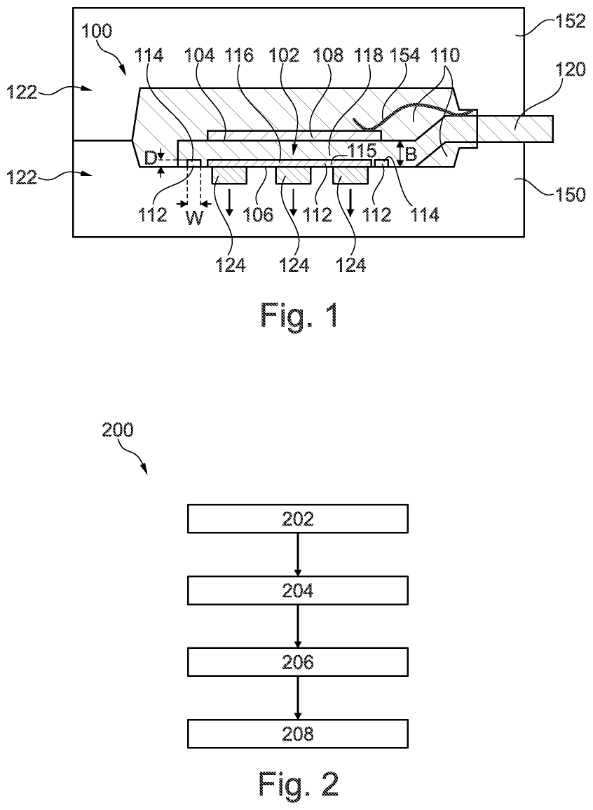

FIG. 1 illustrates a cross-sectional view of a package 100 according to an exemplary embodiment. According to FIG. 1, package 100 is still located inside of an encapsulation tool 122. Hence, FIG. 1 shows package 100 directly at the end of an encapsulation process during manufacture thereof. The illustrated encapsulation tool 122 comprises a bottom part 150 and a top part 152 and delimits in between a hollow space defining the exterior shape of package 100.

Now referring to package 100 in further detail, package 100 comprises a carrier 102. Carrier 102 can be embodied as a leadframe structure, i.e. as a bent and punched metallic plate (for instance made of copper) comprising a die pad 118 and leads 120. Carrier 102 has top-sided front side 104 and an opposing bottom-sided back side 106.

As shown, an electronic component 108 is mounted on the front side 104 of the carrier 102. For example, the electronic component 108 may be a power semiconductor chip. For instance, at least one monolithically integrated circuit element (such as a diode or a transistor) may be monolithically integrated in a semiconductor substrate of the electronic component 108. Although only a single electronic component 108 is mounted on carrier 102 according to FIG. 1, it is also possible in other embodiments that a plurality of electronic components 108 are mounted on the front side 104 of the carrier 102. For instance, the one or more electronic components 102 may be mounted on the carrier 102 by soldering, by sintering or by gluing.

A pad (not shown) of electronic component 108 may be electrically coupled with a lead 120 (or with the die pad 118) of the carrier 102 by an electrically conductive connection element 154. In the shown embodiment, the electrically conductive connection element 154 is embodied as bond wire. Alternatively, electrically conductive connection element 154 may be a clip (not shown).

Still referring to FIG. 1, an encapsulant 110 encapsulates the entire electronic component 108 and part of the carrier 102. However, another part of the carrier 102, namely part of the leads 110 and the back side 106 of the carrier 102, is exposed with respect to the encapsulant 110. The exposed metallic surface of the carrier 102 at its back side 106 may function as a cooling entity and may efficiently remove heat, created by the encapsulated electronic component 108 during operation of package 100, to an exterior thereof. Encapsulant 110 can be a mold compound which mechanically protects and electrically insulates the encapsulated electronic component 108. However, encapsulant 110 has a relatively poor thermal conductivity, so that the exposure of the back side 106 of the carrier 102 is of utmost advantage for the thermal reliability and performance of package 100.

Before the description of the construction of package 100 will be continued, reference is made to a specific aspect of its manufacturing method. During said manufacture, the constituents of the package 100 are arranged inside of the encapsulation tool 122. To ensure that the back side 106 of the carrier 102 remains exposed with respect to the encapsulant 110, the back side 106 of the carrier 102 is placed on a bottom of the encapsulation tool 122 during encapsulation (see FIG. 1) so that flowable encapsulant material is prevented from covering back side 106 of carrier 102 during molding (in particular during injection molding). In order to further promote this, the carrier 102 is actively pulled towards the bottom of the encapsulation tool 122 by applying a vacuum suction force through the bottom of the encapsulation tool 122 during encapsulating. For this purpose, vacuum suction openings 124 of the encapsulation tool 122 are placed in communication with a portion of the back side 106 of the carrier 102 at a central vacuum suction enhancing indentation 112 which is embodied as a cavity 116. Moreover, said central vacuum suction enhancing indentation 112 is surrounded by a closed loop groove 114 formed in the back side 106 of the carrier 102 as well and constituting a peripheral vacuum suction enhancing indentation 112. Since the peripheral vacuum suction enhancing indentation 112 surrounds the central vacuum section enhancing indentation 112, the latter forms an interior indentation 115.

Advantageously, the back side 106 of the carrier 102 has the peripheral vacuum suction enhancing indentation 112 embodied as closed loop groove 114 for enhancing vacuum suction of the carrier 102 during encapsulation. Said peripheral vacuum suction enhancing indentation 112 is configured for inhibiting flow of flowable encapsulant material towards a central portion of the back side 106 of the carrier 102. Thus, peripheral vacuum suction enhancing indentation 112 ensures that the back side 106 of the carrier 102 or at least a major portion thereof remains free of encapsulant 110. Furthermore, the central vacuum suction enhancing indentation 112 arranged in alignment with the vacuum suction openings 124 of the encapsulation tool 122 enhances the vacuum suction of the carrier 102 onto the bottom-sided encapsulation tool 122. Thus, the back side 106 of the carrier 102 may be placed on the bottom of the encapsulation tool 122, and the carrier 102 may be pulled towards the bottom by applying the vacuum suction force by the vacuum suction openings 124 through the bottom of the encapsulation tool 122 during encapsulating. A resulting strong vacuum suction force exerted to a central portion of the back side 106 of the carrier 102 may efficiently enhance flatness of the carrier 102 during the vacuum suction process. By preventing the carrier 102 from bending or experiencing warpage during encapsulation, exposure of the back side 106 of the carrier 102 from encapsulant 110 is additionally promoted. Thus, the described vacuum suction enhancing indentations 112 cooperate for inhibiting a flow of encapsulant 110 during encapsulation to the central portion of the exposed back side 106.

To achieve this effect, it is preferred that the peripheral vacuum suction enhancing indentation 112 is shaped as a circumferentially closed groove 114. Said groove 114 may be rectangular, circular or oval, but preferably of closed loop type. Advantageously, the groove 114 may have a width W of for example 100 μm and a depth, D, of for example 30 μm.

In addition, the central vacuum suction enhancing indentation 112 is embodied as interior indentation 115 in an interior of the circumferentially closed groove 114 and is formed as continuous two-dimensional cavity 116. For example, the continuous two-dimensional cavity 116 is rectangular, circular or oval. For instance, the central vacuum suction enhancing indentation 112 may have a depth in a range from 25 μm to 30 μm.

As shown in FIG. 1, the encapsulant 110 and the carrier 102 together delimit the entire exterior surface of the package 100. Since the package 100 is configured as tie bar-less package without tie bar and in particular without tie bar extending up to the outline of the package 100, no metallic tie bar can negatively influence the electrical reliability of the package 100.

Furthermore, depth D of the vacuum suction enhancing indentations 112 may be significantly smaller than a thickness B of the carrier 102 being for example 700 μm. This may ensure that the front side 104 of the carrier 102 remains flat regardless of the surface profile on the back side 106 forming the vacuum suction enhancing indentations 112. A flat front face 104 of the carrier 102 is advantageous, since it allows a highly precise assembly of the electronic component 108 thereon. Moreover, the absence of a clamping pin, thanks to the vacuum suction during encapsulation, keeps the entire front face 104 available for assembly of one or more electronic components 108. In particular, this allows the assembly of very large dies.

For example, the vacuum suction enhancing indentations 112 may be formed in a very simple way by coining, thereby preventing any undesired influence on the front side 104.

Advantageously, the central vacuum suction enhancing indentation 112 may form a cavity 116 with vacuum contact at carrier 102. The latter, being exposed at its back side 106, functions as heat sink during operation of the package 100. Further advantageously, a selective vacuum mold manufacturing process may be applied as an alternative to a conventional pin clamping for manufacturing tie bar-less package 100. The described manufacturing architecture also enables to form a fully insulated package 100. Moreover, sufficient space even for larger die sizes may be ensured at the front side 104 of the carrier 102 of package 100. This enables, in turn, manufacture of a high voltage package with large die size. Advantageously, a selective vacuum function may be established in the mold cavity of encapsulation tool 122.

The vacuum suction enhancing indentations 112 provide a special feature at a heat sink-type carrier 102 to enhance the suction of its die pad 118 during the mold (or more generally encapsulation) process. The illustrated and described arrangement of vacuum suction enhancing indentations 112 leads to a pronounced planarity of the die pad 118 of the carrier 102 and may reliably prevent undesired mold flow to the bottom of the die pad 118. For example, the empty groove 114 forming peripheral vacuum suction enhancing indentation 112 may accommodate excessive mold material which is therefore prevented from flowing to the bottom of the die pad 118. The central vacuum suction enhancing indentation 112 may cooperate with the vacuum suction openings 124 for enhancing vacuum suction efficiency and for promoting planarity. The omission of a pin (also denoted as mold ear) may also prevent the space consumption of such a feature, therefore rendering package 100 compatible with a large die as electronic component 108.

FIG. 2 illustrates a flowchart 200 of a method of manufacturing a package 100 according to an exemplary embodiment. The reference signs used for the following description of said manufacturing method relate to the embodiment of FIG. 1.

Referring to a block 202, the method comprises providing a carrier 102 having a front side 104 and a back side 106.

Referring to a block 204, the method comprises mounting an electronic component 108 on the front side 104 of the carrier 102.

Referring to a block 206, the method comprises at least partially encapsulating the electronic component 108 and partially encapsulating the carrier 102 by an encapsulant 110 so that the back side 106 is at least partially exposed with respect to the encapsulant 110.

Referring to a block 208, the method comprises applying a vacuum suction force to the back side 106 of the carrier 102 during the encapsulating, wherein the back side 106 of the carrier 102 has at least one vacuum suction enhancing indentation 112 for enhancing the vacuum suction of the carrier 102.

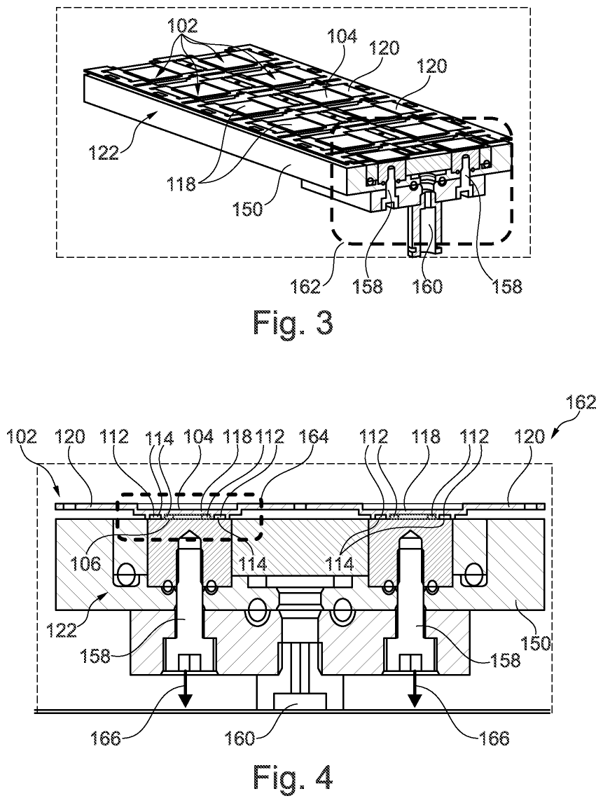

FIG. 3 to FIG. 5 illustrate different views of arrangements during manufacturing a package 100 according to an exemplary embodiment.

Referring to FIG. 3, a leadframe comprising a plurality of carriers 102, embodied as leadframe structure, is shown. The carriers 102, each comprising a die pad 118 and a plurality of leads 120, are placed on the bottom part 150 of the encapsulation tool 122 (the top part 152 thereof is not shown in FIG. 3 to FIG. 5). A vacuum source 160, such as a vacuum pump, provides a vacuum suction force exerted to the back side 106 of the die pads 118. Vacuum nozzles 158, which may relate to vacuum suction openings 124 (not visible in FIG. 3), may exert a vacuum force to the die pads 118 for pulling the latter downwardly towards the bottom part 150 of the encapsulation tool 122. To put it shortly, FIG. 3 illustrates a mold bottom cavity design providing a selective vacuum to hold the heat sink-type die pads 118.

For creating a vacuum suction force, it may be possible to provide one main channel per vacuum suction cavity (and thus one main channel per carrier 102). However, there may be branches extending from such a main channel to split the main channel into a plurality of subchannels leading to vacuum suction openings 124.

Referring to FIG. 4, a cross-sectional view of a detail 162 of the arrangement of FIG. 3 is illustrated. Detail 162 of FIG. 3 illustrates the heat sink-type die pads 118 with groove-type vacuum suction enhancing indications 112, for instance embodied as shown in FIG. 9. Arrows 166 indicate the direction of the created selective vacuum force.

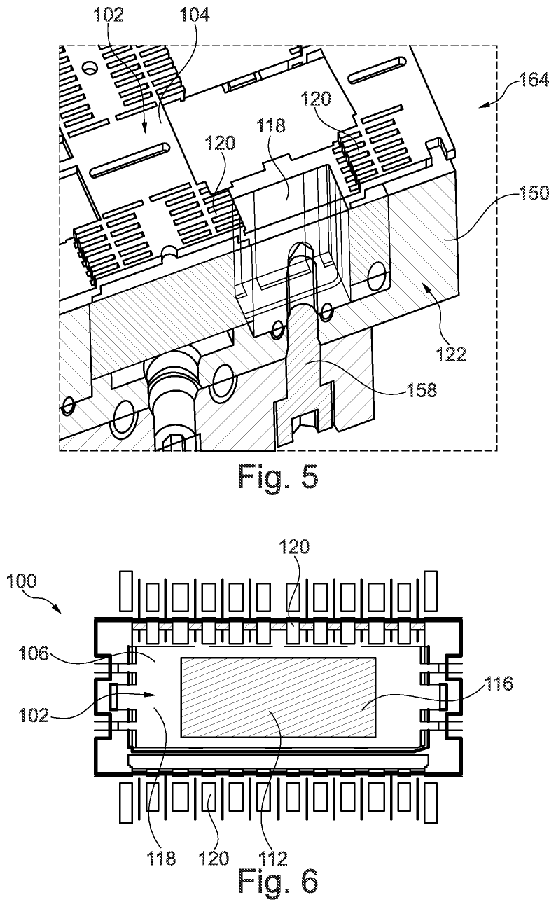

Referring to FIG. 5, a three-dimensional view of a further detail 164 of the arrangement of FIG. 4 is illustrated. The vacuum suction area is arranged on the back side 106 of the leadframe-type die pad 118. In particular, a bottom-sided heat sink groove 114 may form a vacuum suction enhancing indentation 112 design contributing to the vacuum suction towards the die pad 118.

FIG. 6 illustrates a plan view of a package 100 according to an exemplary embodiment. More specifically, a back side 106 of a carrier 102 of package 100 is shown.

According to FIG. 6, a vacuum suction enhancing indentation 112 is provided which is embodied as a continuous two-dimensional cavity 116 on the back side 106 of die pad 118 of carrier 102. In the shown embodiment, said vacuum suction enhancing indentation 112 is formed as a shallow recess. While the vacuum suction enhancing indentation 112 is of rectangular shape according to FIG. 6, it may also have another shape, for instance a circular or oval shape. The illustrated vacuum suction enhancing indentation 112 is configured for enhancing flatness of the carrier 102 during vacuum suction when interacting with one or more vacuum suction openings 124 (not shown in FIG. 6). The embodiment of FIG. 6 provides a good planarity.

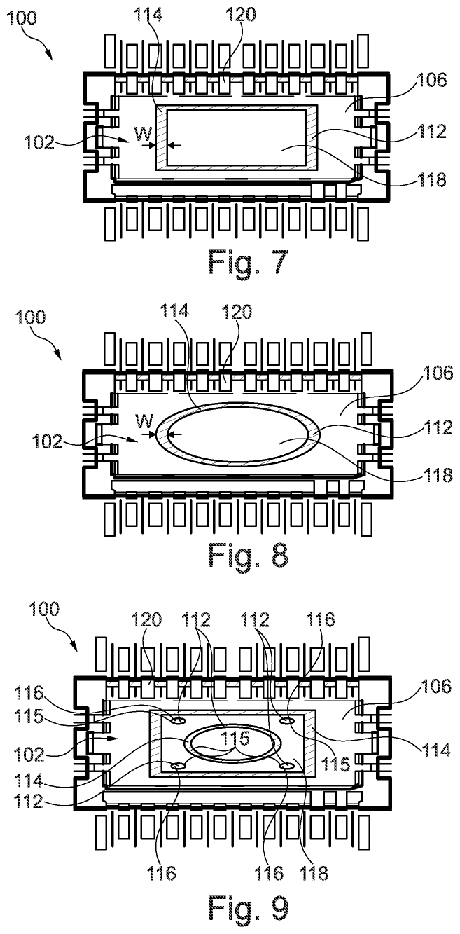

FIG. 7 illustrates a plan view of a package 100 according to an exemplary embodiment. More specifically, a back side 106 of a carrier 102 of package 100 is shown.

According to FIG. 7, a vacuum suction enhancing indentation 112 is provided which is embodied as a circumferentially closed groove 114 on the back side 106 of die pad 118 of carrier 102. While the vacuum suction enhancing indentation 112 is of closed rectangular groove type according to FIG. 7, it may also have another shape and/or may be an open structure rather than a closed loop. The illustrated vacuum suction enhancing indentation 112 is configured for inhibiting a flow of encapsulant 110, during encapsulation, to the exposed central back side 106. The embodiment of FIG. 7 provides a good protection against mold bleed. In the central area inside of and delimited by the groove-type vacuum suction enhancing indentation 112, an efficient vacuum suction may be enabled.

FIG. 8 illustrates a plan view of a package 100 according to an exemplary embodiment. More specifically, a back side 106 of a carrier 102 of package 100 is shown.

The embodiment of FIG. 8 differs from the embodiment of FIG. 7 in particular in that, according to FIG. 8, the groove-type vacuum suction enhancing indentation 112 has an oval shape rather than a rectangular shape. Corresponding effects and advantages, as described referring to FIG. 7, can also be obtained with the embodiment of FIG. 8.

FIG. 9 illustrates a plan view of a package 100 according to a preferred exemplary embodiment. More specifically, a back side 106 of a carrier 102 of package 100 is shown.

According to FIG. 9, a plurality of vacuum suction enhancing indentations 112 are formed on the back side 106 of die pad 118 of carrier 102. An exterior (for example rectangular) circumferentially closed groove 114 functions primarily as a protection against mold bleeding. Thus, said exterior circumferentially closed groove 114 may stop flashes. For example, the exterior circumferentially closed groove 114 may have a width of 100 μm and a depth in a range from 30 μm to 35 μm. Inside of said exterior circumferentially closed groove 114, a further circumferentially closed groove 114 (for example oval) is arranged. Also said additional circumferentially closed groove 114 may function as an additional protection against mold bleeding, while contributing as well to an improved vacuum suction in a surface portion of the back side of die pad 118 delimited by said additional circumferentially closed groove 114. Hence, the latter may also promote planarity of carrier 102. The most important function provided by the additional circumferentially closed groove 114 may be its positive impact on the vacuum suction area. For example, the additional circumferentially closed groove 114 may have a width of 100 μm and a depth of 30 μm. In addition, the embodiment of FIG. 9 comprises a plurality of (four in the shown example) further vacuum suction enhancing indentations 112 inside of the exterior groove-type vacuum suction enhancing indication 112 which are embodied as cavities 116. In the shown embodiment, said cavities 116 have an oval or circular shape, but may also have another shape. For example, the cavities 116 may be rings or may be continuous two-dimensional areas. These additional cavities 116 also contribute to planarity and may functionally cooperate with vacuum suction openings 124 (not shown in FIG. 9). The most important function provided by the cavities 116 may be their positive impact on the vacuum suction area. For example, the cavities 116 may be embodied as rings which may have a width of 100 μm and a depth in a range from 20 μm to 25 μm. The embodiment of FIG. 9 may provide the lowest risk to prevent flashes during a molding process. Hence, this embodiment may optimize the vacuum suction attributes for holding the heat sink-type die pad 118.

Preferably, the depth of the grooves 114 of the heat sink-type die pad 118 may be 30 μm, and its width may be 100 μm.

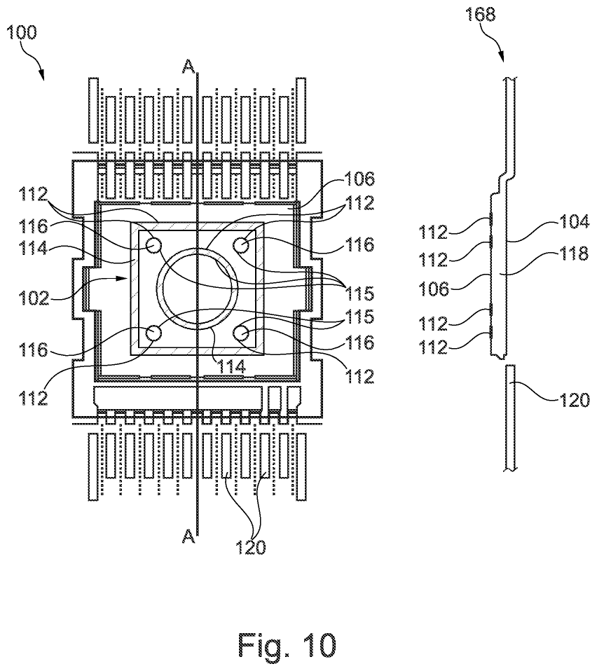

FIG. 10 illustrates a plan view and a cross-sectional view of a package 100 according to an exemplary embodiment. More specifically, different views of a carrier 102 of package 100 are shown.

The embodiment of FIG. 10 correspond to the embodiment of FIG. 9, but shows additionally a cross-sectional view 168 along a line A-A.

Descriptively speaking, the most central (for example circular or oval) groove-type vacuum suction enhancing indentation 112 may function for enhancing vacuum suction of die pad 118.

In addition, the exterior groove-type vacuum suction enhancing indentation 112 may function as a safety zone preventing bleed of mold towards an interior region of die pad 118. Moreover, said vacuum suction enhancing indentation 112 may also improve the support of carrier 102.

The cooperating groove-type vacuum suction enhancing indentations 112 of FIG. 10 may hold the die pad 118 in the middle, may protect against tilting of carrier 102 and may ensure that there are no gaps between carrier 102 and the bottom-sided encapsulation tool 122.

The cooperating ring-shaped or two-dimensional cavities 116 additionally contribute to a flat surface. Moreover, they may, in the event of tilting, ensure that vacuum suction at the corners of die pad 118 will be enhanced to counteract against tilting.

The cross-sectional view 168 of FIG. 10 illustrates some of the described vacuum suction enhancement indentations 112, i.e. grooves 114. The exterior groove-type vacuum suction enhancement indentation 112 may be configured for preventing flashes getting into the vacuum suction area. It may have a depth of 30 μm. The additional groove-type vacuum suction enhancement indentation 112 inside of the exterior groove-type vacuum suction enhancement indentation 112 may be configured for enhancing the vacuum suction area. It may have a depth in a range from 20 μm to 25 μm. The design according to FIG. 10 may allow to advantageously adjust the vacuum for holding a heat sink.

Summarizing, exemplary embodiments may provide fully isolated packages with a tiebarless design and no need of retractable pins. Advantageously, exemplary embodiments may have no strict limitation on chip size as there is no need for a pin for mechanically clamping a die pad. Advantageously, it may be possible to reduce mold flashes as the die pad is not hanging during molding. Descriptively speaking, the mold vacuum location may be at a center of a heat sink to prevent a vacuum leak. Advantageously, there is no need for a mold ear clamping area to clamp the heat sink towards a bottom cavity during encapsulation. Thus, exemplary embodiments may enable die pad holding towards a bottom cavity by using cavity vacuum suction. Hence, a clamp-free fully isolated package with tiebarless concept and selective vacuum implementation for higher voltage requirements may be provided.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a carrier having a front side and a back side;
an electronic component mounted on the front side of the carrier; and
an encapsulant at least partially encapsulating the electronic component and partially encapsulating the carrier so that the back side is at least partially exposed with respect to the encapsulant; and
wherein the back side of the carrier has at least one vacuum suction enhancing indentation for enhancing vacuum suction of the carrier during encapsulation.

2. The package according to claim 1, wherein the at least one vacuum suction enhancing indentation is configured for enhancing flatness of the carrier during vacuum suction.

3. The package according to claim 1, wherein the at least one vacuum suction enhancing indentation is configured for inhibiting a flow of encapsulant during encapsulation to the at least partially exposed back side.

4. The package according to claim 1, wherein the at least one vacuum suction enhancing indentation comprises a, for example circumferentially closed, groove.

5. The package according to claim 4, wherein the groove is rectangular, circular or oval.

6. The package according to claim 4, wherein the groove has a width in a range from 50 μm to 200 μm, in particular from 70 μm to 150 μm.

7. The package according to claim 4, wherein the at least one vacuum suction enhancing indentation comprises at least one interior indentation in an interior of the circumferentially closed groove.

8. The package according to claim 1, wherein the at least one vacuum suction enhancing indentation comprises at least one continuous two-dimensional cavity and/or at least one ring-shaped cavity.

9. The package according to claim 8, wherein the continuous two-dimensional cavity is rectangular, circular or oval.

10. The package according to claim 1, wherein the encapsulant and the carrier together delimit the entire exterior surface of the package.

11. The package according to claim 1, wherein the electronic component is a power semiconductor chip.

12. The package according to claim 1, configured as tie bar-less package.

13. The package according to claim 1, wherein the carrier is a leadframe structure.

14. The package according to claim 1, wherein the carrier comprises a die paddle, on which the electronic component is mounted and which has the at least one vacuum suction enhancing indentation, and comprises at least one lead.

15. The package according to claim 1, wherein a depth of the at least one vacuum suction enhancing indentation is in a range from 5 μm to 100 μm, in particular in a range from 10 μm to 30 μm.

16. The package according to claim 1, wherein a thickness of the carrier is in a range from 200 μm to 1200 μm, in particular in a range from 500 μm to 900 μm.

17. The package according to claim 1, wherein the front side of the carrier is flat.

18. A method of manufacturing a package, wherein the method comprises:
providing a carrier having a front side and a back side;
mounting an electronic component on the front side of the carrier;
at least partially encapsulating the electronic component and partially encapsulating the carrier by an encapsulant so that the back side is at least partially exposed with respect to the encapsulant; and
applying a vacuum suction force to the back side of the carrier during the encapsulating, wherein the back side of the carrier has at least one vacuum suction enhancing indentation for enhancing the vacuum suction of the carrier.

19. The method according to claim 18, wherein the method comprises forming the at least one vacuum suction enhancing indentation by at least one of the group consisting of coining, mechanical abrasion, and etching.

20. The method according to claim 18, comprising at least one of the following features:
wherein the method comprises placing the back side of the carrier on a bottom of an encapsulation tool and pulling the carrier towards the bottom by applying the vacuum suction force through the bottom of the encapsulation tool during encapsulating; and
wherein the method comprises placing at least one vacuum suction opening of an encapsulation tool onto a portion of the back side of the carrier during encapsulating, which portion has the at least one vacuum suction enhancing indentation.
